(19) United States
(12) Patent Application Publication
(10) Pub. No.: US 2020/0096806 A1
(43) Pub. Date: Mar. 26, 2020

(54) BACKLIT CURVED DISPLAY DEVICE

(71) Applicant: FLEXENABLE LIMITED, Cambridge (GB)

(72) Inventor: William REEVES, Cambridge (GB)

(73) Assignee: FLEXENABLE LIMITED, Cambridge (GB)

(21) Appl. No.: 16/576,054

(22) Filed: Sep. 19, 2019

(30) Foreign Application Priority Data
Sep. 20, 2018 (GB) 1815350.2

(51) Int. Cl. G02F 1/1333; H05K 1/02; G02F 1/1335

(52) U.S. Cl. CPC G02F 1/133305; G02F 1/133602; G02F 1/133524; H05K 1/028

(57) ABSTRACT

A method of forming a backlit curved display device, comprising: preparing at least one resiliently flexible plastics film component in a substantially planar configuration, which plastics film component forms at least part of an optical modulator component; flexing the plastics film component into a stressed configuration about a curved surface of a backlight component and bonding at least the plastics film component in the stressed configuration to the curved surface of the backlight component.

Some display devices comprise a backlight in combination with an optical modulator to modulate the light from the backlight.

The inventor for the present application has conducted research into the production of curved devices of this kind.

There is hereby provided a method of forming a backlit curved display device, comprising: preparing at least one resiliently flexible plastics film component in a substantially planar configuration, which plastics film component forms at least part of an optical modulator component; flexing the plastics film component into a stressed configuration about a curved surface of a backlight component and bonding at least the plastics film component in the stressed configuration to the curved surface of the backlight component.

According to one embodiment, the curved backlight component comprises a curved light guide component which is configured to guide light from outside a display output area across the display output area while releasing a portion of the guided light towards the plastics film component.

According to one embodiment, the plastics film component comprises a control component including a support film supporting a stack of conductor, semiconductor and insulator layers defining an array of pixel electrodes independently addressable via conductors outside the array of pixel electrodes; wherein the light guide component is configured to guide light across the array of pixel electrodes from an area outside the array of pixel electrodes, while releasing a portion of the guided light towards the array of pixel electrodes.

According to one embodiment, the plastics film component comprises a liquid crystal cell comprising liquid crystal material contained between said control component and a counter component.

According to one embodiment, the plastics film component comprises plastics film, polarisation filter components on opposing sides of the liquid crystal cell.

According to one embodiment, the curved light guide component includes: a first portion extending across the whole of the display output area; and a second portion extending behind at least part of the first portion; and a bend portion connecting the first and second portions outside the display output area; wherein the light guide component is configured to guide light from said second portion to said first portion via said bend portion.

Using the backlight component also as at least the primary structural support component enables a reduction in thickness of the whole display device, and reduces or eliminates the need for a relatively thick front window as a curved support component. However, the technique does not exclude, for example, the application of a secondary curved support component to the front of the one or more plastics film components in situ on the light guide component.

An embodiment is described in detail, hereunder, by way of example only, with reference to the accompanying drawings, in which:

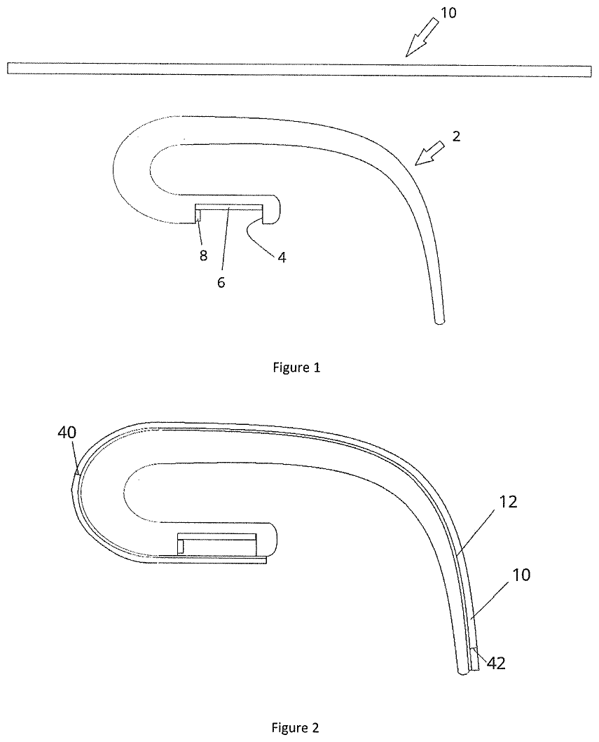

FIG. 1 provides a schematic cross-sectional illustration of a light guide component and a plastics film optical modulator component for bonding together according to a technique according to an embodiment of the invention;

FIG. 2 provides a schematic cross-sectional illustration of the plastics film components and light guide component of FIG. 1 as bonded together via a low refractive index adhesive layer;

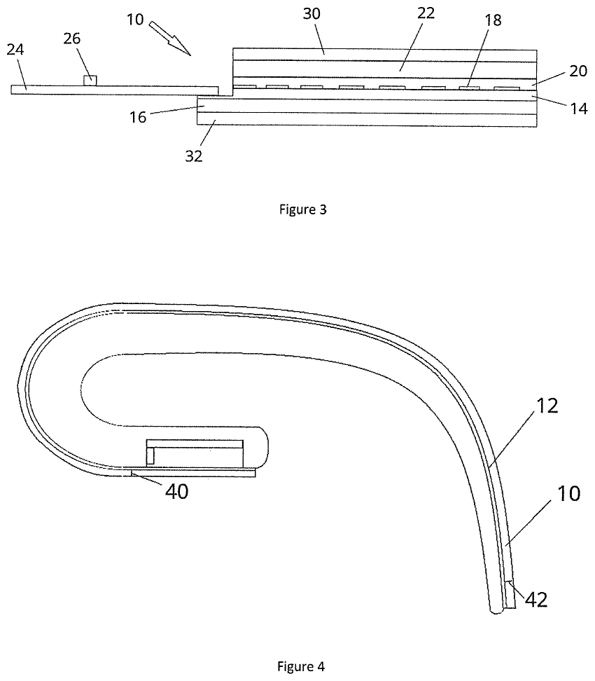

FIG. 3 provides a schematic cross-sectional illustration of an example of a plastics film optical modulator component; and

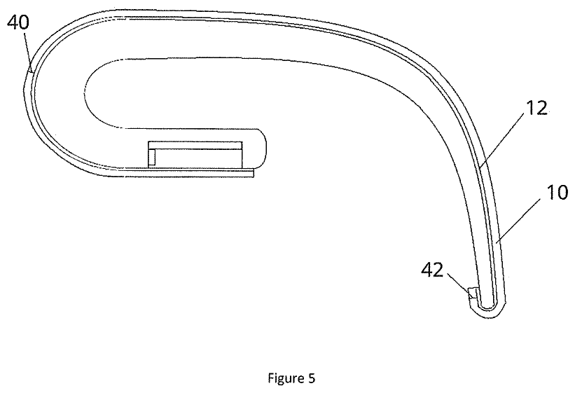

FIG. 4 shows a variation of the embodiment of FIG. 1; and

FIG. 5 shows another variation of the embodiment of FIG. 1.

An embodiment of the invention is described below for the example of the production of an organic liquid crystal display (OLCD) device, which comprises an organic transistor device (such as an organic thin film transistor (OTFT) device) for the control component. OTFTs comprise an organic semiconductor (such as e.g. an organic polymer or small-molecule semiconductor) for the semiconductor channels. However, the same technique is also applicable to the production of e.g. other kinds of liquid crystal display devices, and display devices other than liquid crystal display devices.

The example described below uses a moulded light guide component 2 that bends about 180 degrees around on itself at one edge, but the same technique may alternatively use a light guide component 2 with a smaller bend (e.g. about 90 degrees bend) or substantially no bend at all between the light sources and the start of the display output area (which as mentioned below, may be defined by the total area of an array of pixel electrodes of the device).

The portion of the moulded light guide component 2 in the region of at least the majority of the display output area is set in a curved configuration.

The light guide component 2 defines a recess 4 in a region outside the display output area, which recess 4 houses a printed circuit board 6 including electrical circuitry for controlling the optical output of one more light sources 8, such as light-emitting diodes (LEDs).

In use, the light guide component 2 guides light from the light sources 8 across the display output area while releasing a portion of the guided light towards the plastics film optical modulator component(s), such that the combination of (i) the light sources 8 outside the display output area and (ii) the light guide component 2 serves as a backlight for the display device across the whole of the display output area.

In this example, the thickness of the light guide component 2 reduces gradually towards an edge of the light guide component most remote from the light sources 8. This thickness tapering aids light extraction from the light guide component 2 into the optical modulator component(s), and enables a reduction of the mass of the display device outside areas where a relatively large thickness may be advantageous for coupling large amounts of light from the light sources 8 into the light guide component 2.

A resiliently flexible plastics film component 10 prepared in a substantially planar resting configuration and constituting part or all of an optical modulator is then forcibly flexed into a stressed configuration about the curved surface of the light guide component 2 and bonded in the stressed configuration to the light guide component 2 via a layer of low refractive index (RI) adhesive 12 over substantially the whole area of the plastics film component 10. As mentioned above, the plastics film component 10 is resiliently flexible; when the plastics film component 10 is forcibly flexed away from its planar resting configuration, internal stresses are generated within the plastics film component, which act to return the plastics film component 10 to its planar resting configuration.

The low RI adhesive has a RI lower than the RI of the light guide component 2, so as to promote the guiding of light from the light sources 8 across the whole of the display output area. The bonding may, for example, be achieved by a dry bond lamination technique using a pre-formed layer of low RI adhesive.

As mentioned below, in one example, the plastics film component 10 comprises a set of pre-prepared plastics film sub-components that are bonded together in their respective substantially planar resting configurations before being bonded as a unit to the light guide component 2. In another example, the pre-prepared individual plastics film sub-components are bonded together in situ on the light guide component 2. In more detail, each plastics film sub-component of the set of sub-components is, in turn, individually forcibly flexed into a stressed configuration about the curved surface of the light guide component and bonded in the stressed configuration to the light guide component 2 over substantially the whole area of the respective plastics film sub-component, via any plastics film sub-component(s) that has already been bonded to the light guide component 2.

Each bonding may, for example, be achieved by a dry bond lamination technique.

In this example, the curved light guide component 2 has a bending stiffness sufficiently high to render unnecessary the use of a more rigid lamination aid, but a lamination aid may be used to temporarily support the curved light guide component 2 during the process of forcibly flexing the plastics film (sub-)components about the curved surface of the light guide component 2. In this example, the curved light guide component 2 has a bending stiffness higher than the bending stiffness of the plastics film component(s) bonded to the light guide component. In any case, the adhesive bond between the curved light guide component 2 and the plastics film component(s) 10 over substantially the whole area of the plastics film component(s) 10 holds the resulting assembly in a curved configuration, against at least the tendency of the plastics film component(s) 10 to relax back to a substantially planar configuration.

In one example, the optical modulator comprises a set of three pre-prepared plastics film sub-components: a lower polarising filter component 32; a liquid crystal cell incorporating electrical control circuitry and a colour filter array, and pre-bonded to a chip-on-flex (COF) unit; and an upper polarising filter component 30. In this example, all three sub-components are prepared in respective substantially planar resting configurations and bonded together in their planar resting configurations, before bonding the assembly 10 in a stressed configuration to the light guide component 2. An example of the plastics film component 10 is schematically illustrated in FIG. 3. A stack 14 of conductor, semiconductor and insulator layers is formed in situ on a plastics support film 16. The stack 14 defines an array of pixel electrodes 18, and electrical circuitry for independently controlling each pixel electrode via conductors outside the array of pixel electrodes 18. The stack 14 may, for example, define an active matrix array of thin-film transistors, including: an array of gate conductors each providing the gate electrode for a respective row of TFTs, and extending to outside the array of pixel electrodes; and an array of source conductors each providing the source electrode for a respective column of TFTs, and extending to outside the array of pixel electrodes. Each pixel electrode is associated with a respective TFT, and each TFT is associated with a unique combination of gate and source conductors, whereby each pixel electrode can be addressed independently of all other pixel electrodes.

A substantially uniform thickness of liquid crystal material 20 is contained between the array of pixel electrodes 18 and a counter component 22 comprising an array of colour filters supported on another plastics support film. A COF unit 24 is bonded to a portion of the support film 16 outside the array of pixel electrodes 18 to create a conductive connection between (i) an array of conductors (e.g. source and gate addressing conductors) defined by the stack 14 in a region outside the array of pixel electrodes 18 and (ii) a corresponding array of conductors of the COF unit, which are connected to the terminals of one or more driver chips 26 forming part of the COF unit. In one example, this plastics film component 10 is configured in relation to the light guide component 2 such that the array of pixel electrodes 18 extends partly around the 180 degree bend at the edge of the light guide component 2 (such that the display output area extends partly around this bend as shown in FIG. 1, and may in one variation shown in FIG. 4 extend completely around this bend); and the one or more driver chips 26 of the COF unit 24 (bonded to the LC cell component) are located in a region of the light guide component beyond the 180 degree bend. In FIG. 2, opposing edges of the array of pixel electrodes (i.e. opposing edges of the display output area) are indicated by numerals 40 and 42.

According to one variation of FIG. 1 or FIG. 4, the display output area may extend around the opposite, distal edge (edge most remote from the light sources 8) of the light guide component 2, as shown in FIG. 5. An edge portion of the plastics film component 10 is forcibly bent into a stressed configuration around the distal edge of the light guide component 2, and bonded to the light guide component 2 in this stressed configuration.

The LC cell includes alignment layers (e.g. rubbed polyimide layers) on both sides of the LC material to control the orientation of the LC director in the absence of an electric field generated by a potential difference between a pixel electrode and a counter electrode. The counter electrode may be on the same side of the liquid crystal material as the pixel electrode (such as in the case of a fringe field switching (FFS) device) or may be on the opposite side of the liquid crystal material to the pixel electrode (in which case, it may be constituted by a conductor layer forming part of the counter component 22 including the CFA array).

In addition to the optical modulator component 10, plastics film components with other functionality may additionally be bonded to the light guide component 2. According to one example, this is done either before or after bonding the optical modulator component 10 to the light guide component 2. According to another example, this is done by bonding one or more additional plastics film components to the optical modulator component 10 in a planar configuration, before bonding the resulting bonded assembly in a stressed configuration to the light guide component 2. For example, a plastics film component providing touch sensor functionality and also prepared in a substantially planar resting configuration may be bonded to the curved light guide component 2 via the optical modulator component 10. Also, a plastics film component (also prepared in a substantially planar resting configuration) may be bonded to the curved light guide component via the optical modulator component 10 (and via the touch sensor component, if used) to provide a protective cover.

Using a light guide component as the primary curved support component (if not the only curved support component) can have the following advantages: reducing the number of parts to be assembled (laminated) together; and facilitating a reduction in the thickness of a protective plastics film cover at the front of the display device. Reducing the thickness of a front cover can be advantageous for: easing viewing angle restrictions; improving the performance of the touch sensor component 4; and facilitating the use of surface finishing treatments for the curved support component, such as a matte-finish treatment to reduce the specular reflection of external light incident on the curved support component.

In addition to any modifications explicitly mentioned above, it will be evident to a person skilled in the art that various other modifications of the described embodiment may be made within the scope of the invention.

The applicant hereby discloses in isolation each individual feature described herein and any combination of two or more such features, to the extent that such features or combinations are capable of being carried out based on the present specification as a whole in the light of the common general knowledge of a person skilled in the art, irrespective of whether such features or combinations of features solve any problems disclosed herein, and without limitation to the scope of the claims. The applicant indicates that aspects of the present invention may consist of any such individual feature or combination of features.

1. A method of forming a backlit curved display device, comprising: preparing at least one resiliently flexible plastics film component in a substantially planar configuration, which plastics film component forms at least part of an optical modulator component; flexing the plastics film component into a stressed configuration about a curved surface of a backlight component and bonding at least the plastics film component in the stressed configuration to the curved surface of the backlight component.

2. The method according to claim 1, wherein the curved backlight component comprises a curved light guide component which is configured to guide light from outside a display output area across the display output area while releasing a portion of the guided light towards the plastics film component.

3. The method according to claim 2, wherein the plastics film component comprises a control component including a support film supporting a stack of conductor, semiconductor and insulator layers defining an array of pixel electrodes independently addressable via conductors outside the array of pixel electrodes; wherein the light guide component is configured to guide light across the array of pixel electrodes from an area outside the array of pixel electrodes, while releasing a portion of the guided light towards the array of pixel electrodes.

4. The method according to claim 3, wherein the plastics film component comprises a liquid crystal cell comprising liquid crystal material contained between said control component and a counter component.

5. The method according to claim 4, wherein the plastics film component comprises plastics film, polarisation filter components on opposing sides of the liquid crystal cell.

6. The method according to claim 2, wherein the curved light guide component includes: a first portion extending across the whole of the display output area; and a second portion extending behind at least part of the first portion; and a bend portion connecting the first and second portions outside the display output area; wherein the light guide component is configured to guide light from said second portion to said first portion via said bend portion.
